(19) United States
(12) Patent Application Publication
(10) Pub. No.: US 2012/0090172 A1
(43) Pub. Date: Apr. 19, 2012

(54) Method of manufacturing printed circuit boad

(75) Inventors: Moon Soo Park, Suwon-si (KR); Sung Hyun Kim, Suwon-si (KR); Choon Keun Lee, Suwon-si (KR); Song Hee Jung, Suwon-si (KR)

(73) Assignee: SAMSUNG ELECTRO-MECHANICS CO., LTD., Suwon (KR)

(21) Appl. No.: 12/929,461

(22) Filed: Jan. 26, 2011

(30) Foreign Application Priority Data
Oct. 18, 2010 (KR) 10-2010-0101382

(51) Int. Cl. H05K 3/22

(52) U.S. Cl. 29/846

(57) ABSTRACT

Disclosed herein is a method of manufacturing a printed circuit board, including: forming a first circuit wiring layer on a substrate; forming an organic metal compound layer on the surface of the first circuit wiring layer; performing a surface treatment on the surface of the organic metal compound layer; forming an insulating layer on the first circuit wiring layer including the organic metal compound layer; and forming a second circuit wiring layer on the insulating layer.

### CROSS REFERENCE(S) TO RELATED APPLICATIONS

This application claims the benefit under 35 U.S.C. Section [120, 119, 119(e)] of Korean Patent Application Serial No. 10-2010-0101382, entitled “Method Of Manufacturing Printed Circuit Board” filed on Oct. 18, 2010, which is hereby incorporated by reference in its entirety into this application.

### BACKGROUND OF THE INVENTION

1. Technical Field

The present invention relates to a printed circuit board, and more particularly, to a method of manufacturing a printed circuit board capable of preventing a lift defect between a circuit wiring layer and an insulating layer.

2. Description of the Related Art

With the recent demand for improvement in performance and miniaturization of electronic communication apparatuses, the field of printed circuit board has been developed day by day, in particular, a multilayer wiring substrate formed with a plurality of circuit wiring layers are formed to increase density of the circuit wiring layer.

The multilayer wiring substrate may be formed through a buildup process including: forming a substrate including lower wirings, forming an insulating layer on the substrate including the lower circuit wiring layer, forming via holes in the insulating layer; and forming upper wirings on the insulating layer including the via holes. Herein, the forming the upper wirings may include forming an electroless plating layer on the insulating layer and performing an electroplating process selectively precipitating plate on the electroless platting layer.

However, adhesion between a conductor pattern forming wirings and the insulating layer is not good, thereby causing a lift defect between the wirings and the insulating layer during a process for forming the multilayer wiring substrate.

### SUMMARY OF THE INVENTION

An object of the present invention is to provide a method of manufacturing a printed circuit board that forms an organic metal compound layer on a circuit wiring layer and then a surface treatment is performed on the organic metal compound layer to prevent a lift defect between the circuit wiring layer and the insulating layer.

According to an exemplary embodiment of the present invention, there is provided a method of manufacturing a printed circuit board, including: forming a first circuit wiring layer on a substrate; forming an organic metal compound layer on the surface of the first circuit wiring layer; performing a surface treatment on the surface of the organic metal compound layer; forming an insulating layer on the first circuit wiring layer including the organic metal compound layer; and forming a second circuit wiring layer on the insulating layer.

Herein, the organic metal compound layer may be made of an azo-based compound including a metal configuring the first circuit wiring layer and a complex compound

The organic metal compound layer may be formed through a brown oxide process.

At the performing the surface treatment on the surface of the organic metal compound layer, a thickness of the organic metal compound layer may be reduced.

After the performing the surface treatment on the surface of the organic metal compound layer, the organic metal compound layer may have a thickness of 0.3 μm to 0.7 μm.

The performing the surface treatment on the surface of the organic may include using a composition including an alkaline aqueous solution.

The method of manufacturing a printed circuit board may further include performing a roughness treatment on the surface of the insulator between the forming the insulating layer on the first circuit wiring layer including the organic metal compound layer and the forming the second circuit wiring layer.

### BRIEF DESCRIPTION OF THE DRAWINGS

FIG. 1 is a flow chart showing a manufacturing process of a printed circuit board according to an exemplary embodiment of the present invention;

FIGS. 2 to 7 are cross-sectional views showing a manufacturing process of a printed circuit board according to an exemplary embodiment of the present invention;

FIG. 8 is a cross-sectional photograph of a printed circuit board according to Comparative Example; and

FIG. 9 is a cross-sectional photograph of a printed circuit board according to Example of the present invention.

### DESCRIPTION OF THE PREFERRED EMBODIMENTS

Hereinafter, the exemplary embodiments of the present invention will be described in detail with reference to the drawings of a printed circuit board. The exemplary embodiments of the present invention to be described below are provided by way of example so that the idea of the present invention can be sufficiently transferred to those skilled in the art to which the present invention pertains.

Therefore, the present invention may be modified in many different forms and it should not be limited to the embodiments set forth herein. In the drawings, the size and the thickness of the apparatus may be exaggerated for convenience. Like reference numerals denote like elements throughout the specification.

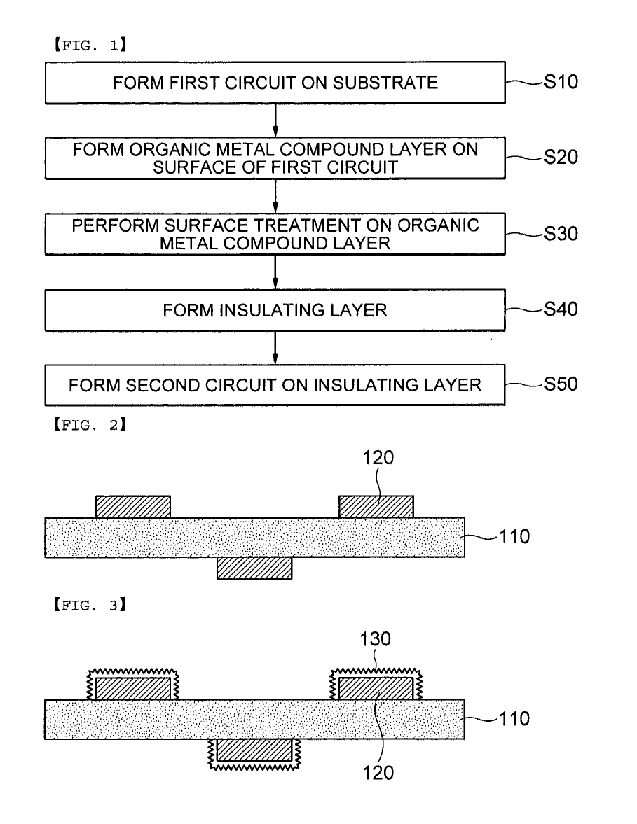

FIG. 1 is a flow chart showing a manufacturing process of a printed circuit board according to an exemplary embodiment of the present invention.

FIGS. 2 to 7 are cross-sectional views showing a manufacturing process of a printed circuit board according to an exemplary embodiment of the present invention.

Referring to FIGS. 1 and 2, a first circuit wiring layer 120 is first formed on a substrate 110 in order to manufacture a printed circuit board.

In this case, the substrate 110 may include a reinforcement and a resin impregnated into the reinforcement. As the reinforcement, a glass fiber may be used by way of example. As the resin, an epoxy-based resin, a polyimide-based resin, a triazine-based resin, or the like may be used by way of example. However, the material of the substrate 110 is not limited in the embodiment of the present invention but the substrate 110 may be made of ceramic or wafer.

The first circuit wiring layer 120 may be made of metal, such as copper, gold, silver, nickel, or the like.

The forming the first circuit wiring layer 120 on the substrate 110 may include forming a plating resist pattern on a copper foil of a copper clad laminate, that is, a semi additive process (SAP) scheme; selectively performing a plating process on the copper foil using the plating resist pattern; and removing the copper foil corresponding to the plating resist pattern.

However, the embodiment of the present invention is not limited thereto but the first circuit wiring layer 120 may also be formed on the substrate by other schemes, for example, an additive process scheme, a subtractive process scheme, a modified semi additive process (MSAP) scheme, or the like.

Meanwhile, the substrate is shown to be provided as a single layer but is not limited thereto. For example, the substrate may be a multilayer printed circuit board including a plurality of circuit wiring layers and an insulating layer. In addition, a double-sided printed circuit board having the first circuit wiring layers 120 provided on both surfaces of the substrate 110 is shown but the present embodiment is not limited thereto. A single sided printed circuit board having the first circuit wiring layer 120 provided on one surface of the substrate may also be used (S10).

Referring to FIGS. 1 and 3, after the first circuit wiring layer 120 is formed, an organic metal compound layer 130 is formed on the surface of the first circuit wiring layer 120.

In this case, the organic metal compound layer 130 may be made of an azo-based complex compound including a metal configuring the first circuit wiring layer 120.

The organic metal compound layer 130 may be formed through a brown oxide process. The brown oxide process may be performed by dipping the substrate 110 including the first circuit wiring layer 120 in a brown oxide composition. In this case, the brown oxide composition may include a liquid mixture of a sulfuric acid and peroxide, and an azo-based compound. As the azo-based compound, benzotriazole and 5-aminotetrazole may be used by way of example. At this time, the first circuit wiring layer 120 is etched using a strong acid. Therefore, a roughness may be formed on the surface of the first circuit wiring layer 120. In addition, during the process the azo-based compound forms a metal configuring the first circuit wiring layer and a complex compound due to peroxide, and the azo-based compound may be bonded to the surface of the first circuit wiring layer. In other words, the organic metal compound layer 130 may be made of the azo-based complex compound including a metal configuring the first circuit wiring layer 120 and the complex compound.

Therefore, the organic metal compound layer 130 may form a complex compound with the surface of the first circuit layer 120, that is, be chemically bonded thereto. In addition, the surface of the organic metal compound layer 130 is formed of an organic layer, thereby making it possible to secure adhesion with an insulating layer 140 described below. That is, the organic metal compound layer 130 may improve adhesion between the first circuit wiring layer 120 and the insulating layer 140 (S20).

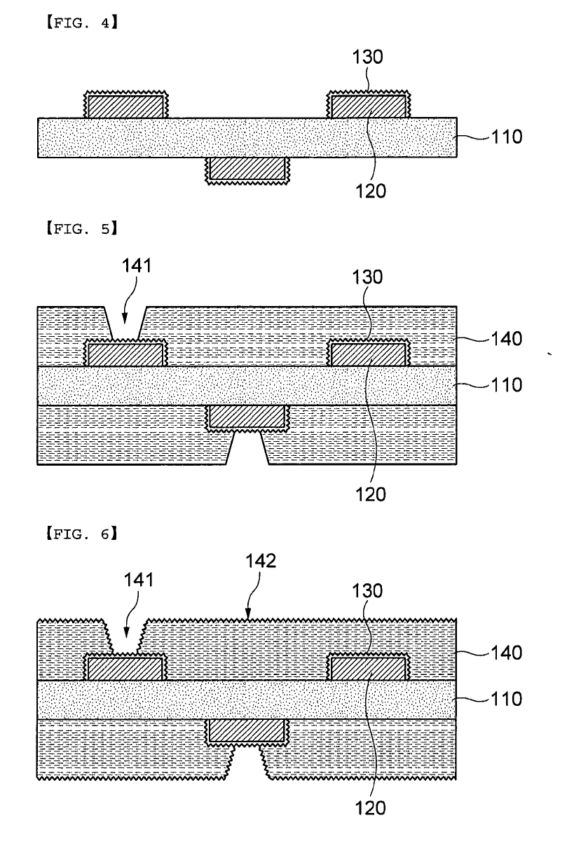

Referring to FIGS. 1 and 4, the organic metal compound layer 130 is formed on the surface of the first circuit wiring layer 120 and then, a surface treatment is performed on the organic metal compound layer 130.

The thickness of the organic metal compound layer 130 may be reduced through the surface treatment. In this case, the organic metal compound layer 130 may have a thickness of 1 μm or less. The reason is that when the organic metal compound layer 130 has a thickness exceeding of 1 μm, a crevice may be formed during a dismear process, a subsequent process. The organic metal compound layer 130 may preferably have a thickness of 0.3 μm to 0.7 μm. In this case, when the organic metal compound layer 130 has a thickness below 0.3 μm, there may be no effect in improving adhesion between the organic metal compound layer 130 and the insulating layer 140 due to the roughness of the organic metal compound layer 130.

The surface treatment may be performed on the surface of the organic metal compound layer 130 by using a composition including an alkaline aqueous solution. At this time, the surface treatment may be performed on the surface of the organic metal compound layer 130 by dipping the substrate 110 including the organic metal compound layer 130 in the composition. In this case, as the alkaline aqueous solution, sodium hydroxide may be used by way of example. In addition, the composition may further include a surfactant. During the process, the organic layer on the surface of the organic metal compound layer 130 may be removed and at the same time, the roughness of the organic metal compound layer 130 may be reduced.

In other words, the organic layer of the organic metal compound layer 130 which may react during the dismear process is previously removed through the surface treatment, thereby making it possible to prevent a crevice from being formed in the organic metal compound layer 130 during the dismear process. The reason is that when the surface treatment is not performed on the organic metal compound layer 130, the organic layer of the organic metal compound layer 130 is etched during the dismear process by the a treatment solution used in the dismear process to form a crevice in the organic metal compound layer 130, such that a lift between the first circuit wiring layer 120 and the insulating layer 140 may occur (S30).

Referring to FIGS. 1 and 5, after the surface treatment is performed on the organic metal compound layer 130, the insulating layer 140 is formed.

Thereafter, the insulating layer 140 may be formed on the substrate 110 including the organic metal compound layer 130 through a lamination. However, the exemplary embodiment is not limited thereto but the insulating layer 140 may also be formed by applying an insulating resin.

Thereafter, a via hole 141 exposing the first circuit wiring layer 120 is formed in the insulating layer 140. The via hole 141 may be formed by performing laser drilling or punching on the insulating layer 140.

Referring to FIGS. 1 and 6, after the insulating layer 140 is formed, a roughness treatment is performed on the surface of the insulating layer 140 including the via hole 141. Thereby, the surface of the insulating layer 140 has a roughness 142, thereby making it possible to secure adhesion between the insulating layer 140 and a second circuit wiring layer 150 described below.

The roughness treatment on the insulating layer 140 may be performed by swelling the insulating layer 140 by a sweller, that is, the dismear process, and then performing oxidation between the sweller of the insulating layer 140 and an etchant. At this time, a smear generated during the process of forming the via hole 141 in the insulating layer 140 may also be removed during the roughness treatment process of the insulating layer 140. In this case, the etchant may include sodium hydroxide or potassium hydroxide.

In addition, it is possible to prevent a crevice from being formed in the organic metal compound layer 130 during the dismear process, thereby making it possible to prevent a lift defect between the insulating layer 140 and the first circuit wiring layer 120 due to the dismear process (S40).

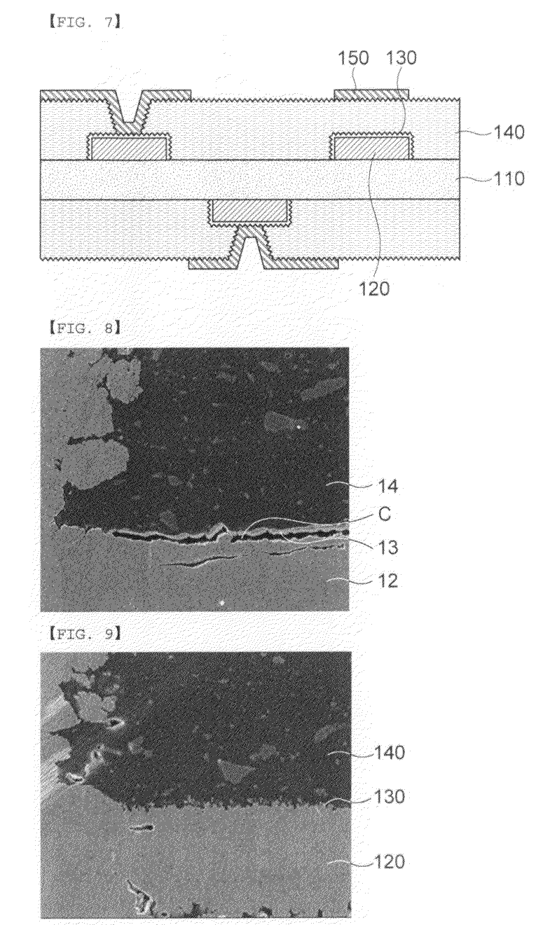

Referring to FIGS. 1 and 7, after the roughness treatment on the insulating layer 140 is performed, a second circuit wiring layer 150 is formed on the insulating layer 140.

In order to form the second circuit wiring layer 150, an electroless plating is first performed on the insulating layer 140 to form a seed layer. Thereafter, after a plating resist pattern is formed on the seed layer, electroplating using the seed layer is performed, such that the second circuit wiring layer may be formed in a region defined by the plating resist pattern. Thereafter, after the plating resist pattern is removed, the seed layer disposed on the lower portion of the plating resist pattern is removed.

In other words, the second circuit wiring layer 150 may be formed through a semi additive process (SAP) scheme. However, the embodiment of the present invention is not limited thereto but the second circuit wiring layer may also be formed by other schemes, for example, an additive process scheme, a subtractive process scheme, a modified semi additive process (MSAP) scheme, or the like (S50).

During the process of forming the second circuit wiring layer 150, a via provided in the via hole 141 is formed. Thereby, the first and second circuit wiring layers 120 and 150 may be electrically connected to each other through the via.

In addition, a build up process including forming an additional insulating layer or forming an additional circuit wiring layer on the second circuit wiring layer 150 may further be performed. In addition, although not shown on the second circuit wiring layer 150, a process of forming a solder resist may further be performed, when the build-up process is not further performed.

Hereinafter, lift degrees of the insulating layer according to whether or not the surface treatment is performed on the organic metal compound layer will be compared with reference to FIGS. 8 and 9.

FIG. 8 is a cross-sectional photograph of a printed circuit board according to Comparative Example.

FIG. 9 is a cross-sectional photograph of a printed circuit board according to Example of the present invention.

Referring to FIG. 8, it can be appreciated that when the surface treatment is not performed on the organic metal compound layer 13 on the lower circuit wiring layer 12, a crevice C is formed in the organic metal compound layer between the lower circuit wiring layer 12 and the insulating layer 14, such that the insulating layer is lifted from the lower circuit wiring layer 12.

On the other hand, referring to FIG. 9, it can be appreciated that when the surface treatment is performed on the organic metal compound layer 130 on the lower circuit wiring layer 120, a crevice is hardly formed in the organic metal compound layer 130 between the lower circuit wiring layer 120 and the insulating layer 140, such that a lift defect between the insulating layer 140 and the lower circuit wiring layer 120 is not generated.

Therefore, according to the exemplary embodiment of the present invention, after the organic metal compound layer is formed on the lower circuit wiring layer, the insulating layer is stacked thereof, thereby making it possible to secure adhesion between the circuit wiring layer and the insulating layer.

In addition, it is possible to reduce damage to the organic metal compound layer between the circuit wiring layer and the insulating layer during the roughness treatment process of the insulating layer through the surface treatment on the organic metal compound layer, thereby making it possible to prevent a lift defect between the circuit wiring layer and the insulating layer.

With the method of manufacturing a printed circuit board according to the exemplary embodiment of the present invention, after the organic metal compound layer is formed on the circuit wiring layer, the insulating layer is stacked thereon, thereby making it possible to secure adhesion between the circuit wiring layer and the insulating layer.

In addition, it is possible to reduce damage to the organic metal compound layer provided between the circuit wiring layer and the insulating layer during the roughness treatment process of the insulating layer through the surface treatment of the organic metal compound layer, thereby making it possible to prevent a lift defect between the circuit wiring layer and the insulating layer.

Since the exemplary embodiments of the present invention have been described, those skilled in the art should appreciate that that various modifications and equivalent other embodiments may be made. Therefore, it is to be understood that the invention is not limited to the disclosed embodiments, but, on the contrary, is intended to cover various modifications and equivalent arrangements included within the spirit and scope of the appended claims.

What is claimed is:

1. A method of manufacturing a printed circuit board, comprising:
forming a first circuit wiring layer on a substrate;
forming an organic metal compound layer on the surface of the first circuit wiring layer;
performing a surface treatment on the surface of the organic metal compound layer;
forming an insulating layer on the first circuit wiring layer including the organic metal compound layer; and
forming a second circuit wiring layer on the insulating layer.

2. The method of manufacturing a printed circuit board according to claim 1, wherein the organic metal compound layer is made of an azo-based compound including a metal configuring the first circuit wiring layer and a complex compound.

3. The method of manufacturing a printed circuit board according to claim 1, wherein the organic metal compound layer is formed through a brown oxide process.

4. The method of manufacturing a printed circuit board according to claim 1, wherein at the performing the surface treatment on the surface of the organic metal compound layer, a thickness of the organic metal compound layer is reduced.

5. The method of manufacturing a printed circuit board according to claim 4, wherein after the performing the surface treatment on the surface of the organic metal compound layer, the organic metal compound layer has a thickness of 0.3 μm to 0.7 μm.

6. The method of manufacturing a printed circuit board according to claim 1, wherein the performing the surface treatment on the surface of the organic metal compound layer comprises using a composition including an alkaline aqueous solution.

7. The method of manufacturing a printed circuit board according to claim 1, further comprising performing a roughness treatment on the surface of the insulator between the forming the insulating layer on the first circuit wiring layer including the organic metal compound layer and the forming the second circuit wiring layer on the insulating layer.
